(19) United States
(12) Patent Application Publication
(10) Pub. No.: US 2015/0267310 A1
(43) Pub. Date: Sep. 24, 2015

(54) TIN OR TIN ALLOY ELECTROPLATING BATH AND PROCESS FOR PRODUCING BUMPS USING SAME

(71) Applicant: C. Uyemura & Co., Ltd., Osaka (JP)

(72) Inventors: Raihei IKUMOTO, Osaka (JP); Masanobu TSUJIMOTO, Osaka (JP); Toshikazu KANO, Osaka (JP)

(21) Appl. No.: 14/661,450

(22) Filed: Mar. 18, 2015

(30) Foreign Application Priority Data
Mar. 18, 2014 (JP) 2014-055266

(51) Int. Cl. C25D 3/32; H05K 3/40; C25D 5/50; C25D 3/60; C25D 5/02

(52) U.S. Cl. CPC C25D 3/32; C25D 3/60; C25D 5/02; C25D 5/505; H05K 3/4007; H05K 2203/043; H05K 2203/0723; H05K 2203/122

(57) ABSTRACT

A tin or tin alloy electroplating bath and a process for producing a bump using the same are disclosed. The electroplating bath includes an inorganic acid and an organic acid, as well as a water-soluble salt thereof; a non-ionic surfactant selected from the group consisting of polyoxyalkylene phenyl ethers, polyoxyalkylene polycyclic phenyl ethers, and salts thereof; and leveling agents containing at least one selected from the group consisting of aliphatic aldehydes, aromatic aldehydes, aliphatic ketones, and aromatic ketones; and at least one selected from the group consisting of α,β-unsaturated carboxylic acids, α,β-unsaturated carboxylic acid amides, and salts thereof. The process includes forming a coating film of a tin or tin alloy on a substrate with an electroplating bath as set forth above; and then performing reflow treatment.

### BACKGROUND OF THE INVENTION

1. Technical Field

The present invention relates to a tin or tin alloy electroplating bath, and a process for producing bumps of the tin or tin alloy on a substrate using the electroplating bath.

2. Background Art

Bumps are protruding metal terminals for connecting integrated circuits to external circuit boards or intermediate substrate circuits, and are formed of, for example, solder (alloys of lead and tin) or lead-free solder (e.g., tin, tin alloys). As production methods of bumps, there have been known, for example, vapor deposition method; plating method such as electroplating; paste printing method; and micro-ball bumping method. As the number of bumps for connection to external circuits has recently been increased with integration and densification of semiconductor device circuits, there has strongly been requested narrowing of bump pitch or downsizing of bump size. Among the above production methods, paste printing methods and micro-ball methods are difficult to meet such a request sufficiently, and therefore, electroplating methods capable of producing narrow pitch or small diameter bumps have received attention.

In the production of a bump by electroplating method, a process has mainly be carried out, in which a resist pattern (including resist openings and holes) is first formed on a substrate and each inside of the resist openings or holes is then subjected to electroplating, thereby forming the bump. The following will describe a general process for producing a bump by electroplating method, while referring to FIG. 1.

First, on the surface of a substrate provided with wiring and others, a solder resist pattern having an opening is formed by lithography using a solder resist. On the surface of the solder resist layer, a metal seed layer (e.g., a copper seed layer in FIG. 1) for power feeding is then formed by deposition method, electroless plating method, or any other method. A dry film resist layer is then formed on the surface of the metal seed layer, and a dry film resist pattern having an opening is formed to connect to the opening of the solder resist layer. The inside of the dry film resist pattern is then subjected to electroplating (e.g., tin electroplating in FIG. 1) by power feeding through the metal seed layer, to form a tin plating film on the metal seed layer. The dry film resist layer and the metal seed layer are then successively removed, and the remaining tin plating film is melt by reflow treatment to form a tin bump.

However, in the above production process, the opening of the solder resist layer and the opening of the dry film resist layer are formed in different sizes, and therefore, a step resulting from the thickness of the solder resist layer is formed on the surface of the metal seed layer. If electroplating is performed in this state as described above, the plating film grows while inheriting the step of the underlying layer, and therefore, an irregular shape called “recess” is unevenly formed on the surface of the plating film as shown in the upper drawing of FIG. 2. From the viewpoint of controlling the thickness of the plating film, it has been desired to form an even electroplating film capable of filling the above recess and being flat and smooth without taking any recess shape after plating as shown in the lower drawing of FIG. 2.

Further, in the case where the smoothing of a plating film is not sufficient, many voids (hollow cavities) tend to be generated in the bumps after the reflow treatment. The generation of voids leads to a lowering in the reliability of the bumps in the connection to circuit boards and others, and therefore, it has been desired to provide an electroplating film having no voids after reflow treatment.

As a technique capable of filling a recess structure without formation of voids, for example, Japanese Patent Laid-open Publication No. 2012-506628 (hereinafter referred to as “Patent Document 1”) discloses a tin and tin alloy plating bath comprising tin ion; an acid; a leveling agent selected from the group consisting of aromatic aldehydes, aromatic ketones, and α-/β-unsaturated carboxylic acids; and an antioxidant.

Moreover, for example, Japanese Patent Laid-open Publication No. 2001-262391 (hereinafter referred to as “Patent Document 2”), although it does not propose from the above point of view, discloses a tin-copper alloy plating bath capable of suppressing the oxidation of Sn²⁺ in the bath, thereby preventing the occurrence of turbidity and exhibiting excellent stability with time. This document teaches that the addition of a specific compound such as methacrylic acid to the tin-copper alloy plating bath can suppress the turbidity of the bath over time. This document further teaches that conventionally known surfactants may be mixed depending on the purpose and exemplifies, such surfactants, various surfactants such as nonionic, cationic, anionic, and amphoteric surfactants, which are used for improving the outer appearance, denseness, smoothness, adhesion, and uniform electrodeposition properties of a plating film.

### SUMMARY OF THE INVENTION

### Problems to be Solved by the Invention

However, the result of the present inventors' studies has found that the plating bath described in Patent Document 1 fails to achieve sufficient filling of recesses and causes the generation of voids.

The present invention has been made in view of the above circumstances, and an object thereof is to provide a novel tin or tin alloy electroplating bath, which can preferably be used for the production of bumps, and which has excellent recess filling property and can suppress the generation of voids, and a process for producing bumps using an electroplating bath as described above.

### Means for Solving the Problems

A tin or tin alloy electroplating bath according to the present invention, which can solve the above problem, comprises:

an inorganic acid and an organic acid, as well as a water-soluble salt thereof;

a non-ionic surfactant selected from the group consisting of polyoxyalkylene phenyl ethers, polyoxyalkylene polycyclic phenyl ethers, and salts thereof,

wherein the phenyl or polycyclic phenyl group in the non-ionic surfactant may be substituted with C₁₋₂₄ alkyl or hydroxy group; and

leveling agents comprising at least one selected from the group consisting of aliphatic aldehydes, aromatic aldehydes, aliphatic ketones, and aromatic ketones; and at least one selected from the group consisting of α,β-unsaturated carboxylic acids, α,β-unsaturated carboxylic acid amides, and salts thereof.

The polycyclic phenyl in the non-ionic surfactant may preferably be styrenated phenyl, naphthyl, cumylphenyl, nonylphenyl, or styrenated cresol.

The oxyalkylene in the non-ionic surfactant may preferably be at least one selected from the group consisting of ethylene oxide and propylene oxide.

The oxyalkylene in the non-ionic surfactant may preferably be a copolymer of ethylene oxide and propylene oxide.

The electroplating bath further comprises at least one selected from the group consisting of thioamide compounds and non-aromatic thiol compounds.

The thioamide compounds may preferably be thiourea, dimethylthiourea, diethylthiourea, trimethylthiourea, N,N′-diisopropylthiourea, acetylthiourea, allylthiourea, ethylenethiourea, thiourea dioxide, thiosemicarbazide, and tetramethylthiourea; and the non-aromatic thiol compounds may preferably be mercaptoacetic acid, mercaptosuccinic acid, mercaptolactic acid, and water-soluble salts thereof.

A process for producing a bump according to the present invention, which can solve the above problem, comprises:

forming a tin or tin alloy coating on a substrate with an electroplating bath as set forth in above; and

then performing reflow treatment.

### EFFECTS OF THE INVENTION

The electroplating bath of the present invention contains both a specific non-ionic surfactant and specific two kinds of leveling agents, so as to have excellent recess filling property and be able to suppress the generation of voids. Therefore, the electroplating bath of the present invention makes it possible to provide favorable bumps having no recess to be smooth and generating no voids after reflow treatment.

### BRIEF DESCRIPTION OF THE DRAWINGS

FIG. 1 is a schematic view for explaining the steps of producing a bump by the electroplating method.

FIG. 2 is a view comparatively showing a plating film having a recess formed on the surface thereof and a plating film having a surface made smooth by filling a recess on the surface thereof.

FIG. 3 is a cross-sectional view for explaining the shapes if substrates (1) and (2) used in Examples.

FIG. 4 is a cross-sectional view for explaining the depth of a recess evaluated in Examples.

FIG. 5 is a view showing the profile of reflow treatment performed for measuring the diameters of voids in Examples.

FIG. 6 is a view for explaining the diameter of a void as evaluated in Examples.

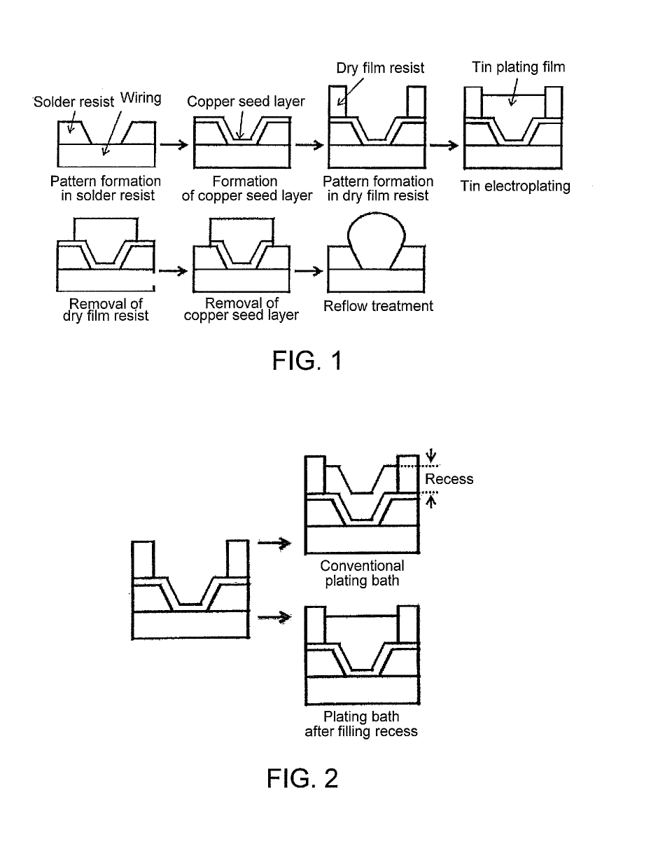

### MODE FOR CARRYING OUT THE INVENTION

For the purpose of providing a novel tin or tin alloy electroplating bath capable of suppressing generation of recesses and voids often observed in the formation of a bump, the present inventors have studied focusing the components (in particular, surfactants and leveling agents) to be added to the plating bath. As a result, they have found that the use of a specific surfactant and specific two kinds of leveling agents is essential to suppress both of these defects to attain the expected purpose. More specifically, they have found that the expected purpose is attained only by the use of:

(1) As the surfactant, at least one non-ionic surfactant selected from the group consisting of polyoxyalkylene phenyl ethers, polyoxyalylene polycyclic phenyl ethers, and salts thereof (the phenyl or polycyclic phenyl group in the non-ionic surfactant may be substituted with C₁₋₂₄ alkyl or hydroxy group); and

(2) As the leveling agents,

(A) At least one selected from the group consisting of aliphatic aldehydes, aromatic aldehydes, aliphatic ketones, and aromatic ketones; and

(B) At least one selected from the group consisting of α,β-unsaturated carboxylic acids, α,β-unsaturated carboxylic acid amides, and salts thereof.

First, the following will describe how the present inventors have reached the above requirements of the present invention.

In an electroplating bath containing tin such as that of the present invention, a surfactant is usually contained for the purpose of forming a uniform plating film without causing the dendrite growth of the tin during the plating. For example, Patent Document 1 recommends using a surfactant as a mild deposition preventing agent capable of promoting the wetting of a substrate or suppressing three-dimensional growth. Patent Document 1 exemplifies, as available surfactants, anionic surfactants including alkyl phosphonates, alkyl ether phosphates, alkyl sulfates, alkyl ether sulfates, alkyl sulfonates, alkyl ether sulfonates, carboxylic acid ethers, carboxylic acid esters, alkyl aryl sulfonates, aryl alkyl ether sulfonates, aryl sulfonates, and sulfosuccinates. However, according to the result of the present inventors' studies, it has been found that the use of such an anionic surfactant causes the formation of recesses and further causes even the generation of voids after reflow treatment (see Comparative Example 5 described in the section entitled “Examples” below).

In addition, according to the result of the present inventors' studies, it has been found that the use of an ampholytic surfactant cannot attain the expected purpose (see Comparative Example 6 described in the section entitled “Examples” below). This Comparative Example 6 simulates the ampholytic surfactant described in Example 8 of Patent Document 2.

Further, according to the result of the present inventors' studies, it has been found that even when a non-ionic surfactant other than those specified herein is used cannot attain the expected purpose (see Comparative Examples 3 and 4 described in the section entitled “Examples” below).

From the results of these experiments, it has been found that the addition of a surfactant with a specific non-ionic structure specified herein, among surfactants, is essential to suppress the formation of recesses (in other words, to make the surface smooth) and further to suppress the generation of voids. As described above, it has been well known that a surfactant has the action of suppressing dendrite formation of tin as the ordinary action of a surfactant in a tin electroplating bath. However, the present knowledge that the above specific non-ionic surfactant has a kind of leveling action, namely “suppression of recesses” that has not hitherto been known, was an extremely surprising unexpected knowledge for the present inventors.

Further, according to the result of the present inventors' studies, it has been found that appropriately controlling the kind of leveling agent, as well as the kind of surfactant, is essential to attain the expected purpose. More specifically, it has also been found that using both of the above (A), such as aliphatic aldehydes, and the above (B), such as α,β-unsaturated carboxylic acids. The kind of leveling agent to be used in the present invention is described even in, for example, Patent Document 1. However, when both of these are not used in combination, the expected effect cannot be obtained; this is a knowledge that has first been found by the present inventors. That is, Patent Document 1 recommends using at least one of the above (A) and (B) to be used in the present invention, but discloses only one example of using benzalacetone alone (one kind) belonging to the above (A), in which the above (B), such as methacrylic acid or acrylic acid, is not used, and demonstrates, in Examples, that the desired effect cannot be obtained by the use of benzalacetone alone (see Comparative Examples 1 and 2 described in the section entitled “Examples” below). The above Comparative Examples 1 and 2 are examples of each containing a specific non-ionic surfactant specified herein and further containing only the above (A) as the leveling agent but containing none of the above (B). From these results, it is found that appropriately controlling the kind of leveling agent, as well as the kind of surfactant, is important for the present invention.

The following will describe in detail about a tin or tin alloy electroplating bath according to the present invention.

(1) Tin or Tin Alloy

The electroplating bath of the present invention is assumed to contain a tin (pure tin) or a tin alloy.

First, in the case of tin, salts containing divalent Sn ion (i.e., Sn²⁺ ion) may preferably be used. The form of tin salt to be used in the present invention is not particularly limited, so long as it is usually used in the field of electroplating baths, but examples thereof may include tin methanesulfonate, tin sulfate, and tin oxide, among which tin methanesulfonate having high solubility is typically used.

The concentration of Sn²⁺ ion in the electroplating bath of the present invention is not particularly limited, so long as it is controlled to provide a desired tin plating film, but it may preferably be about 10 to 100 g/L.

With the progress of plating, the amount of Sn²⁺ ion is decreased, and therefore, it is recommended to use a tin anode as a supply source (or feeding source) of Sn²⁺ ion. On the other hand, in the case of using an insoluble anode, Sn²⁺ ion is not fed from the anode, and therefore, it is preferable to feed a tin salt as described above in a timely manner depending on a decrease in the concentration of Sn²⁺ ion.

Then, in the case of a tin alloy, an alloy component to be used in the present invention is not particularly limited, so long as it is usually used in the plating film, but examples of the metal forming a water-soluble salt may include lead, silver, zinc, bismuth, indium, copper, and nickel. Examples of the above metal salt may include lead salts such as lead oxide , lead methanesulfonate, lead ethanesulfonate, lead isethionate, lead carbonate, and lead acetate; silver salts such as silver sulfates, silver methanesulfonate, silver ethanesulfonate, silver isethionate, silver nitrate, and silver oxide; zinc salts such as zinc methanesulfonate, zinc ethanesulfonate, zinc isethionate, zinc sulfate, zinc chloride, zinc nitrate, and zinc carbonate; bismuth salts such as bismuth sulfate, bismuth methanesulfonate, bismuth ethanesulfonate, bismuth isethionate, bismuth oxide, and bismuth nitrate; indium salts such as indium methanesulfonate, indium ethanesulfonate, indium isethionate, and indium carbonate; copper salts such as copper sulfate, copper (II) oxide, copper methanesulfonate, copper ethanesulfonate, copper isethionate, copper (I) chloride, copper (II) chloride, and copper carbonate; and nickel salts such as nickel sulfate, nickel chloride, nickel sulfamate, nickel carbonate, and nickel bromide.

In view of melting point, connection reliability of bump, and other factors, preferred among the above tin alloys are tin-copper alloy, tin-silver alloy, tin-zinc alloy, tin-lead alloy, tin-bismuth alloy, and tin-silver-copper alloy, with tin-silver alloy being more preferred.

The concentration of alloy component as described above in the electroplating bath may vary depending on the kind of the alloy component, but may preferably be, for example, 0.1 to 50 g/L.

(2) Inorganic Acid and Organic Acid, as Well as Water-Soluble Salts Thereof

An inorganic acid and organic acid are components enhancing the electrical conductivity of an electroplating bath to improve deposition efficiency of plating components (tin or tin alloy). The inorganic acid and organic acid to be used in the present invention are particularly limited, so long as they are usually used in the plating bath, but examples thereof may include inorganic acids such as sulfuric acid, hydrochloric acid, nitric acid, phosphoric acid, and sulfamic acid; and organic sulfonic acids such as alkanesulfonic acid and alkanolsulfonic acid; and carboxylic acids such as aromatic carboxylic acids, aliphatic saturated carboxylic acids, and aminocarboxylic acids. In view of liquid stability and other factors, organic sulfonic acids are preferred with methanesulfonic acid being more preferred.

These acids may be present in their free forms or as water-soluble salts such as water-soluble salts of inorganic acids and water-soluble salts of organic acids. The kinds of the above salts are not particularly limited, so long as they take the form of water-soluble salts, but examples thereof may include potassium slats, sodium salts, ammonium slats, and magnesium salts.

In the present invention, the above inorganic acids and organic acids, as well as water-soluble salts thereof, may be used alone, or two or more kinds thereof may also be used in combination. The above components may preferably be contained in an electroplating bath at an amount (i.e., the amount of one component when the electroplating bath contains it alone, or the total amount of two or more components when the electroplating bath contains them) of about 50 to 300 g/L, more preferably 100 to 300 g/L. If the above components are contained in smaller amounts, their addition effects are not effectively exhibited, thereby deteriorating the stability of the plating bath and tending to easily cause the generation of precipitate. In contrast, even if the above components are excessively added, the addition effects of the above components result in saturation, thereby becoming wasteful.

(3) Specific Non-Ionic Surfactant

As described repeatedly, the present invention has a technical meaning in that a specific surfactant is selected as the surfactant. More specifically, the present invention uses at least one non-ionic surfactant selected from the group consisting of polyoxyalkylene phenyl ethers, polyoxyalkylene polycyclic phenyl ethers, and salts thereof. The phenyl or polycyclic phenyl group in the non-ionic surfactant may be substituted with C₁₋₂₄ alkyl or hydroxy group.

Ordinary surfactants have a hydrophobic group and a hydrophilic group. In the present invention, a non-ionic surfactant of the ether type is selected for use, in which a polyoxyalkylene group (which is a hydrophilic group) such as a polyoxyethylene chain and a polyoxypropylene chain, is added to an aromatic group (which is a hydrophobic group) such as phenyl (benzene ring) or naphthyl (naphthalene ring). The use of such a specific non-ionic surfactant first makes it possible to improve recess filling ability as well as to suppress the generation of voids.

The mechanism that the non-ionic surfactant to be used in the present invention makes it possible to suppress the formation of recesses particularly is not known in details, but is inferred as follows: In general, non-ionic surfactants have plating inhibitory action. When plating on a stepped substrate (more specifically, having a step formed on the surface of a metal seed layer due to the thickness of a solder resist layer) is performed with a plating bath containing a non-ionic surfactant, the supply amount of surfactant becomes greater to the convex portion near the surface than to the concave portion at a deep position in the hole; therefore, the surfactant is adsorbed to the concave portion and the plating inhibitory action becomes larger, whereas the supply amount of surfactant is small to the concave portion; therefore, tin is predominantly deposited to the concave portion. As a result, it is expected that a plating film having a flat surface can be obtained (see the lower drawing in FIG. 2 above); however, recesses are sometimes formed in actual cases. In contrast, the present invention uses, as the non-ionic surfactant, a non-ionic surfactant having an aromatic hydrophobic group larger in size than aliphatic and other groups; therefore, it is inferred that the non-ionic surfactant becomes more difficult to intrude into the concave portion and is further progressed to be adsorbed onto the convex portion, thereby further promoting leveling action to exhibit sufficient recess filling ability.

The polyoxyalkylene group forming the hydrophilic group of a non-ionic surfactant to be used in the present invention is not particularly limited, so long as it is usually used in the field of surfactants. For example, the addition molar number of oxyalkylene (i.e., alkylene oxide) moiety in the polyoxy alkylene group may be preferably 1 to 100, more preferably 1 to 30, and still more preferably 1 to 10. The polyoxyalylene group may have the same kind of oxyalkylene polymerized, or two or more different kinds of oxyalkyelenes copolymerized. The oxyalkylene may preferably have a carbon atom number of 2 to 4, more preferably 2 to 3. The oxyalkylene may be either linear or branched. More specifically, examples thereof may include ethylene oxide (EO), propylene oxide (PO), butylene oxide (BO), and adducts of ethylene oxide (EO) and propylene oxide (PO) with at least one selected from the group consisting of ethylene oxide (EO) and propylene oxide (PO) being preferred, and with adducts of ethylene oxide (EO) and propylene oxide (PO) being more preferred.

Among the phenyl or polycyclic phenyl forming a hydrophobic group of the non-ionic surfactant to be used in the present invention, specific examples of the polycyclic phenyl may include styrenated phenyl with addition of 1 to 3 styrene rings (i.e., monostyrenated phenyl, distyrenated pheyl, and tristyrenated phenyl), naphthyl, cumylphenyl, and nonylphenyl. The above phenyl or polycyclic phenyl may be substituted with, for example, alkyl having 1 to 24 carbon atoms, or hydroxy. Specific examples of the substituted phenyl or polycyclic phenyl may include alkyl-substituted. phenyl (e.g., nonylphenyl) and hydroxy-substituted styrenated phenyl (e.g., styrenated cresol). In view of recess filing property and others, preferred in these specific examples is styrenated phenyl.

In the present invention, commercial available products can be used as the above non-ionic surfactants.

In the present invention, the above non-ionic surfactants may be used alone, or two or more kinds thereof may also be used in combination. The above non-ionic surfactants may preferably be contained in an electroplating bath at an amount (i.e., the amount of one surfactant when the electroplating bath contains it alone, or the total amount of two or more surfactants when the electroplating bath contains them) of about 0.5 to 50 g/L, more preferably 1 to 50 g/L. When the above non-ionic surfactants are contained in smaller amounts, their addition effects cannot effectively be exhibited. In contrast, when the above non-ionic surfactants are excessively added, recesses becomes easily formed.

(4) Specific Two Kinds of Leveling Agents

The electroplating bath of the present invention is further required to contain both two kinds of leveling agents (A) and (B) described below, in addition to the above specific non-ionic surfactant. In general, ordinary leveling agents are contained in plating baths for the purpose of densifying metal films and improving the smoothness of plating films. In the present invention, two kinds of leveling agents described below are used for the purpose of enhancing recess filling ability and suppressing the generation of voids. As described above, components (A) and (B) described below are well-known components as leveling agents. In the past, one of these, particularly leveling agent (A) described below, having large leveling action as shown in, for example, Example of Patent Document 1 described above, has often been used alone. However, it has been found essential to use both of these for suppressing the generation of voids, along with enhancing recess filling property.

(A) At least one selected from the group consisting of aliphatic aldehydes, aromatic aldehydes, aliphatic ketones, and aromatic ketones; and

(B) An α,β-unsaturated carboxylic acid, α,β-unsaturated carboxylic acid, or a salt thereof.

The above (A) and (B) are also disclosed in, for example, Patent Document 1, and even in the present invention, those disclosed in Patent Document 1 can be used. Specific examples are as follows:

The components in the above (A) mean, in short, carbonyl compounds including aldehydes and ketones, but are not intended to include the α,β-unsaturated carboxylic acids recited in the above (B).

Aliphatic aldehydes such as formaldehyde, acetaldehyde, and allylaldehyde;

Aromatic aldehydes such as benzaldehyde, 2-chlorobenzaldehyde, 3-chloro-benzaldehyde, 4-chlorobenzaldehyde, 2,4-dichlorobenzladehyde, 2,6-dichlorobenzaldhyde, 2,4,6-trichlorobenzaldehyde, 1-naphthaldehyde, 2-naphthaldehyde, 2-hydroxybenzaldehyde, 3-hydroxybenzaldehyde, 4-hydroxybenzaldehyde, 2-methylbenzaldhyde, 3-methyl-benzaldhyde, 4-methylbenzaldehyde, m-anisaldehyde, o-anisaldehyde, and p-anisaldehyde;

Aliphatic ketones such as acetylacetone; and

Aromatic ketones such as benzylideneacetone (also called benzalacetone), 2-chloro-acetophenone, 3-chlrooacetophenone, 4-chloroacetophenone, 2,4-dichloroacetophene, and 2,4,6-trichloroacetopheneone.

These may be used alone, or two or more kinds thereof may also be used in combination. The components in the above (A) may preferably be contained in an electroplating bath at an amount (i.e., the amount of one component when the electroplating bath contains it alone, or the total amount of two or more components when the electroplating bath contains them) of about 0.001 to 1 g/L, more preferably 0.01 to 1 g/L. When the above components are contained in smaller amounts, their addition effects cannot effectively be exhibited. In contrast, when the above components are excessively added, smoothing of plating film may possibly be inhibited.

Specific examples of the components in the above (B) may include acrylic acid, methacrylic acid, picolinic acid, crotonic acid, 3-chloroacrylci acid, 3,3-diemthylacrylic acid, 2,3-diemthylacrylic acid, methyl acrylate, ethyl acrylate, n-butyl acrylate, isobutyl acrylate, 2-ethylhexyl acrylate, ethyl methacrylate, n-butyl methacrylate, isobutyl methacrylate, 2-hydroethyl methacrylate, 2-hydroxypropyl methacrylate, 2-dimethylaminoethyl methacrylate, methacrylic anhydride, and methylmethacrylic acid.

Also included in the present invention are amides (e.g., acrylamide) and salts (e.g., potassium, sodium, ammonium, and other salts) of the α,β-unsaturated carboxylic acids exemplified above.

These may be used alone, or two or more kinds thereof may also be used in combination. The components in the above (B) may preferably be contained in an electroplating bath at an amount (i.e., the amount of one component when the electroplating bath contains it alone, or the total amount of two or more components when the electroplating bath contains them) of about 0.01 to 50 g/L, more preferably 0.005 to 10 g/L. When the above components are contained in smaller amounts, their addition effects cannot effectively be exhibited. In contrast, when the above components are contained in too great amounts, smoothing of plating film may possibly be inhibited.

The foregoing described about the basic components to be contained in the electroplating bath of the present invention.

The electroplating bath of the present invention may further contain, within a range where the operation of the present invention is not inhibited, additive components such as contained for the conventional electroplating baths.

<<At least one selected from the group consisting of thioamide compounds and non-aromatic thiol compounds>>

For the purpose of, for example, improving the stability of plating solutions, at least one selected from the group consisting of thioamide compounds and non-aromatic thiol compounds may be contained therein.

Examples of the above thioamide compounds may include thioamide compounds each having 1 to 15 carbon atoms, such as thiourea, dimethylthiourea, diethylthiourea, trimethylthiourea, N,N′-diisopropylthiourea, acetylthiourea, allylthiourea, ethylenethiourea, thiourea dioxide, semicarbazide, and tetramethylthiourea. These may be used alone, or two or more kinds thereof may also be used in combination. Preferred in the above are thiourea, allylthiourea, and tetramethylthiourea.

Examples of the above non-aromatic thiol compounds may include non-aromatic thiol compounds each having 2 to 8 carbon atoms, such as mercaptoacetic acid (thioglycolic acid), mercaptosuccinic acid (thiomalic acid), mercaptolactic acid, and similar acids; and water-soluble salts (e.g., alkali metal salts, ammonium salts, magnesium salts) thereof. These may be used alone, or two or more kinds thereof may also be used in combination. Preferred in the above is mercaptosuccinic acid.

These may be used alone, or two or more kinds thereof may also be used in combination. The above components may preferably be contained in an electroplating bath at an amount (i.e., the amount of one component when the electroplating bath contains it alone, or the total amount of two or more components when the electroplating bath contains them) of 1 to 50 g/L, more preferably 5 to 20 g/L. When the above components are contained in smaller amounts, their addition effects cannot effectively be exhibited. In contrast, when the above components are contained in too great amounts, smoothing of plating film may possibly be inhibited.

<<At Least One of Organic Solvents>>

For the purpose of, for example, making organic additives dispersed in a liquid, at least one of organic solvents may further be contained therein. Specific examples of the above organic solvents may include monohydric alcohols such as 2-propanol; and dihydric alcohols such as ethylene glycol, diethylene glycol, and triethylene glycol.

These may be used alone, or two or more kinds thereof may also be used in combination. The above organic solvents may preferably be contained in an electroplating bath at an amount (i.e., the amount of one organic solvent when the electroplating bath contains it alone, or the total amount of two or more organic solvents when the electroplating bath contains them) of 5 to 100 g/L.

<<Other Surfactants>>

As described repeatedly, the present invention has a technical meaning in that a specific non-ionic surfactant is used; however, surfactants other than that can be used as well in combination with that, if within a range where the operation of the present invention is not inhibited.

For example, in order to improve solubility in a plating solution, anionic surfactants may also be contained, which are derived by addition of sulfonic groups to the specific non-ionic surfactants described above. Specific examples of the anionic surfactants may include sodium salts of polyoxyethylene polycyclic phenyl ether sulfuric acid esters.

Alternatively, for the purpose of improving the wetting property of a substrate, surfactants other than the above (more specifically, non-ionic surfactants, anionic surfactants, cationic surfactants, other than the above) may also be contained. The surfactants are not particularly limited, examples of which may include those used in ordinary electroplating baths. For example, non-ionic surfactants such as polyoxyalkylene adduct of ethylenediamine and polyoxyalkylene adduct of decyl ether; and anionic surfactants such as polyoxyalkylene adduct of sodium lauryl sulfate, which were used in Examples described below, can also be used, if in combination with the specific non-ionic surfactants specified herein.

These may be used alone, or two or more kinds thereof may also be used in combination. The above surfactants may preferably be contained in an electroplating bath at an amount (i.e., the amount of one surfactant when the electroplating bath contains it alone, or the total amount of two or more surfactants when the electroplating bath contains them) of 0.5 to 50 g/L.

<<Antioxidants>>

For example, antioxidants may also be contained. The antioxidants have the action of preventing the oxidation of divalent Sn ions and other additive components contained in an electroplating bath, thereby stabilizing the electroplating bath. The above antioxidants are not particularly limited, so long as they are used in ordinary electroplating baths, but specific examples thereof may include catechol, hydroquinone, and 4-methoxyphenol.

These may be used alone, or two or more kinds thereof may also be used in combination. The above antioxidants may preferably be contained in an electroplating bath at an amount (i.e., the amount of one antioxidant when the electroplating bath contains it alone, or the total amount of two or more antioxidants when the electroplating bath contains them) of 0.1 to 10 g/L.

The following will describe a process for producing a bump with an electroplating bath as described above

The process for producing a bump according to the present invention comprising: forming a tin or tin alloy coating film on a substrate with an electroplating bath as described above; and then performing reflow treatment. The production process of the present invention is characterized in that a plating bath as described above in the present invention is used as the electroplating bath, and ordinary steps may be employed as the other requirements, which steps have usually been used in the conventional process for producing a bump.

For example, glass epoxy substrates may preferably be used as the above substrate.

In addition, a method for forming a tin or tin alloy coating film by electroplating is also not particularly limited.

Further, a method for performing reflow treatment is also not particularly limited. For example, reflow treatment may preferably be performed after application of flux.

The bump thus obtained is extremely useful because of having excellent recess filling ability to be smooth and having suppressed generation of voids.

The present application claims the benefit of priorities from Japanese Patent Application No. 2014-055266, filed on Mar. 18, 2014, and Japanese Patent Application No. 2014-055266, filed on Mar. 18, 2014, both the entire contents of which are incorporated herein by reference.

### EXAMPLES

The present invention will hereinafter be described more specifically by way of Examples, but the present invention is not limited to the following Examples. The present invention can be put into practice after appropriate modifications or variations within a range meeting the gist described above and below, all of which are included in the technical scope of the present invention.

### Examples 1 to 10

To examiner the usefulness of specific non-ionic surfactants and leveling agents specified herein, plating baths containing various components (metal salt, acid, surfactant, leveling agents, and if necessary, thioamide compound and antioxidant) shown in Table 1 below were prepared to perform electrolytic tin plating on substrates shown in Table 1 below, followed by measurement of recess depth and void diameter.

More specifically, in the case of tin plating, metal salt (1) was used, and in the case of tin alloy plating, metal salts (1) and (2) were used. Each of the specific non-ionic surfactants as defined in the present invention is shown as surfactant (1), along which hydrophobic groups (e.g., tristyrenated phenyl) are described just under it. The above surfactants (1) and (2) are as follows:

Polyoxyethylene-polyoxypropylene adduct of tristyrenated phenyl ether (BLAUNON KTSP-1604P available from Aoki Oil Industrial Co., Ltd.);

Polyoxyalkylene adduct of polystyrenated phenyl ether ammonium sulfate (HITENOL NF-13 available from Dai-ichi Kogyo Seiyaku Co., Ltd.);

Polyoxyalkylene adduct of polystyrenated phenyl ether (NEWCOL 2608-F available from Nippon Nyukazai Co, Ltd.);

Polyoxyalkylene adduct of distyrenated phenyl ether (EMULGEN A-90 available from Kao Corporation);

Polyoxyalkylene adduct of naphthyl ether (having addition molar numbers of 16 for polyoxyethylene and 4 for polyoxypropylene);

Polyoxyalkylene adduct of phenyl ether (NEWCOL BNF5-M available from Nippon Nyukazai Co, Ltd.);

Polyoxyalkylene adduct of cumyl phenyl ether (having addition molar numbers of 20 for polyoxyethylene and 4 for polyoxypropylene);

Polyoxyethylene-polyoxypropylene adduct of nonyl phenyl ether (BLAUNON NPP-9506 available from Aoki Oil Industrial Co., Ltd.);

Polyoxyalkylene adduct of distyrenated cresol (having addition molar numbers of 16 for polyoxyethylene and 4 for polyoxypropylene); and

2-Undecyl-1-carboxymethyl-1-hydroxyethylimidazoliumbetaine.

For two kinds of leveling agents specified herein, component (A) (i.e., at least one selected from the group consisting of aliphatic aldehydes, aromatic aldehydes, aliphatic ketones, and aromatic ketones) is shown as leveling agent (1), and component (B) (i.e., an α,β-unsaturated carboxylic acid, α,β-unsaturated carboxylic acid amide, or a salt thereof) is shown as leveling agent (2).

Then, using plating baths having the compositions as described above, electrolytic plating was performed in such a manner as described below.

First, as shown in Table 1, two glass epoxy substrates (1) and (2) were prepared.

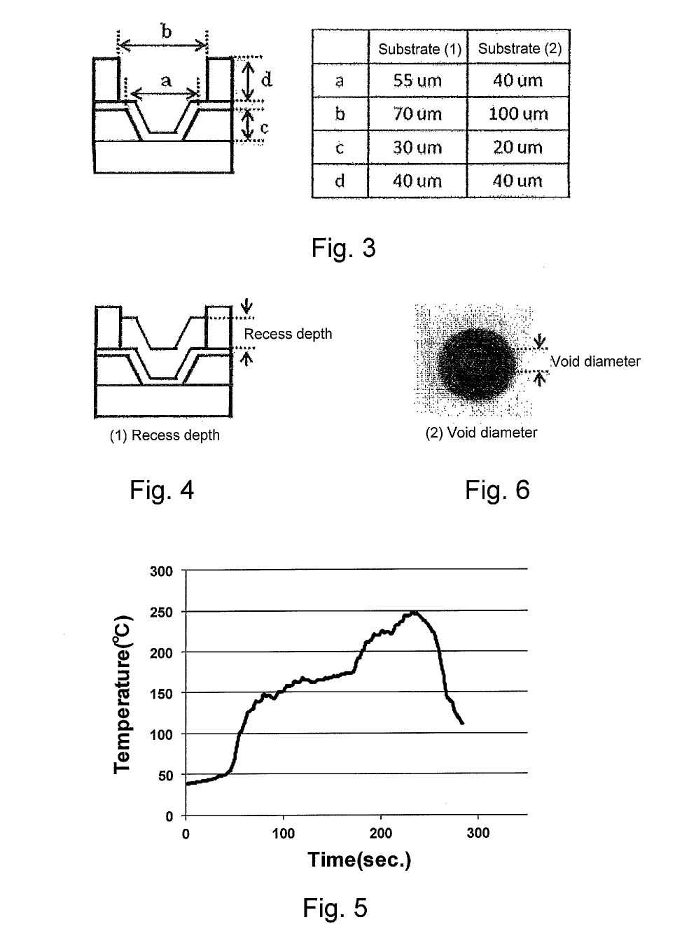

More specifically, substrates having the shape as shown in FIG. 3 were prepared. In FIG. 3, “a” means the opening diameter of each solder resist layer; “b”, the opening diameter of each dry film layer; “c”, the thickness of each solder resist layer; and “d”, the thickness of each dry film layer.

Substrate (1): the opening diameter “a” of each solder resist layer=55 μm, the thickness “c” thereof=30 μm, the opening diameter “b” of each dry film layer=70 μm, and the thickness “d” thereof=40 μm.

Substrate (2): the opening diameter “a” of each solder resist layer =40 μm, the thickness “c” thereof=20 μm, the opening diameter “b” of each dry film layer=100 μm, and the thickness “d” thereof=40 μm.

Then, on the above substrates, electrolytic plating was performed under the following conditions. Each plating film was formed to have a thickness of about 30 pm from the surface of each solder resist layer.

Plating bath temperature: 30° C.

Current density: 2 A/dm²

Plating time: 30 minute

For each plating film obtained in such a manner, recess depth and void diameter were measured in such a manner as described below.

Measurement of Recess Depth:

The surface of each plating film was measured using confocal microscope 0130 available from Lasertech Corporation, and the depth from the highest point (protruding parts) to the lowest point (recessed parts) of each plating film was taken as the recess depth as shown in FIG. 4. These Examples were evaluated as “acceptable” (i.e., having excellent recess filling ability and being smooth) when the recess depth was not greater than 10 μm or as “unacceptable” when the recess depth was greater than 10 μm.

Measurement of Void Diameter

Each plating film was melted by reflow treatment with a reflow profile as shown in FIG. 5 to form a bump, and the diameter of each of various voids generated in the inside of the bump (see FIG. 6) was measured using X-ray inspection apparatus XD7600NT Diamond available from Nordson Advanced Technology Japan K.K., formerly named Dage Japan Co., Ltd. These Examples were evaluated as “acceptable” (i.e., causing no generation of voids) when the largest void has a diameter of not greater than 10 μm or as “unacceptable” when the diameter was greater than 10 μm.

The results are shown together in Table 1.

TABLE 1A

| | | Example 1 | Example 2 | Example 3 | Example 4 | Example 5 |
|---|---|---|---|---|---|---|
| Substrate | | Substrate (1) | Substrate (1) | Substrate (1) | Substrate (2) | Substrate (1) |
| Composition | Metal salt (1) | Tin methane- | Tin methane- | Tin methane- | Tin methane- | Tin sulfate |
| of plating bath | | sulfonate | sulfonate | sulfonate | sulfonate | 170 g/L |
| | | 170 g/L | 170 g/L | 170 g/L | 170 g/L | |
| | Metal salt (2) | — | — | — | — | Copper sulfate |
| | | | | | | 2 g/L |
| | Acid | Methane- | Methane- | Methane-sulfonic | Methane-sulfonic | Sulfuric acid |
| | | sulfonic acid | sulfonic acid | acid | acid | 100 g/L |
| | | 100 g/L | 100 g/L | 100 g/L | 100 g/L | |
| | Thioamide | — | — | — | — | Thiourea |
| | compound | | | | | 5 g/L |
| | Surfactant (1) | Polyoxyethylene- | Polyoxyalkylene | Polyoxyalkylene | Polyoxyethylene- | Polyoxyalkylene |
| | | polyoxypropylene | adduct of | adduct of | polyoxypropylene | adduct of |
| | | adduct of | polystyrenated | polystyrenated | adduct of | polystyrenated |
| | | tristyrenated | phenyl ether | phenyl ether | distyrenated | phenyl ether |
| | | phenyl ether | ammonium sulfate | 0.5 g/L | phenyl ether | ammonium sulfate |
| | | 1 g/L | 5 g/L | | 30 g/L | 5 g/L |
| | | Tristyrenated | Polystyrenated | Polystyrenated | Distyrenated | Polystyrenated |
| | | phenyl | phenyl | phenyl | phenyl | phenyl |
| | Surfactant (2) | — | — | Polyoxyalkylene | — | — |
| | | | | adduct of ethylene | | |
| | | | | diamine | | |
| | | | | 5 g/L | | |
| | Leveling | 2-Chloro- | 1-Naphth- | Benzalacetone | Benzalacetone | 1-Naphth- |
| | agent (1) | benzaldehyde | aldehyde | 0.1 g/L | 0.01 g/L | aldehyde |
| | | 0.01 g/L | 0.01 g/L | | Formaldehyde | 0.01 g/L |
| | | | | | 1 g/L | |
| | Leveling | Methacrylic acid | Picolinic acid | Acrylic acid | Acrylamide | Picolinic acid |
| | agent (2) | 0.5 g/L | 1.0 g/L | 0.03 g/L | 0.005 g/L | 1.0 g/L |
| | Antioxidant | Catechol | — | Hydroquinone | 4-Methoxy-phenol | 4-Methoxy-phenol |
| | | 1 g/L | | 0.5 g/L | 0.2 g/L | 0.2 g/L |
| Evaluation | Recess depth | Acceptable | Acceptable | Acceptable | Acceptable | Acceptable |
| | | (1.1 μm) | (1.3 μm) | (1.7 μm) | (1.4 μm) | (1.2 μm) |
| | Void diameter | Acceptable | Acceptable | Acceptable | Acceptable | Acceptable |
| | | (none) | (none) | (none) | (none) | (none) |

TABLE 1B

| | | Example 6 | Example 7 | Example 8 | Example 9 | Example 10 |
|---|---|---|---|---|---|---|
| Substrate | | Substrate (1) | Substrate (1) | Substrate (1) | Substrate (2) | Substrate (1) |
| Composition | Metal salt (1) | Tin methane- | Tin methane- | Tin methane- | Tin methane- | Tin sulfonate |
| of plating bath | | sulfonate | sulfonate | sulfonate | sulfonate | 170 g/L |
| | | 170 g/L | 170 g/L | 170 g/L | 170 g/L | |
| | Metal salt (2) | — | — | — | — | — |
| | Acid | Methane- | Methane- | Methane- | Methane- | Methane- |
| | | sulfonic acid | sulfonic acid | sulfonic acid | sulfonic acid | sulfonic acid |
| | | 100 g/L | 100 g/L | 100 g/L | 100 g/L | 100 g/L |
| | Thioamide | — | — | — | — | — |
| | compound | | | | | |
| | Surfactant (1) | Polyoxyalkylene | Polyoxyalkylene | Polyoxyalkylene | Polyoxyethylene- | Polyoxyalkylene |
| | | adduct of naphthyl | adduct of | adduct of cumyl | polyoxypropylene | adduct of |
| | | ether | phenyl ether | phenyl ether | adduct of | distyrenated |
| | | 1 g/L | 10 g/L | 1 g/L | nonyl phenyl ether | cresol |
| | | | | | 30 g/L | 5 g/L |
| | | Naphtyl | Phenyl | Cumyl phenyl | Nonyl phenyl | Distyrenated |
| | | | | | | cresol |
| | Surfactant (2) | — | — | — | — | — |
| | Leveling | 2-Chloro- | Benzalacetone | 2-Chloro- | 1-Naphth- | Benzalacetone |
| | agent (1) | benzaldehyde | 0.05 g/L | benzaldehyde | aldehyde | 0.1 g/L |
| | | 0.05 g/L | | 0.05 g/L | 0.01 g/L | formaldehyde |
| | | | | | | 0.5 g/L |
| | Leveling | Methacrylic acid | Methacrylic acid | Methacrylic acid | Acrylic acid | Acrylic acid |
| | agent (2) | 1.0 g/L | 1.0 g/L | 0.05 g/L | 0.005 g/L | 0.005 g/L |
| | Antioxidant | — | — | Catechol | Hydroquinone | 4-Methoxyphenol |
| | | | | 1 g/L | 0.5 g/L | 1 g/L |
| Evaluation | Recess depth | Acceptable | Acceptable | Acceptable | Acceptable | Acceptable |
| | | (2.5 μm) | (4.5 μm) | (2.8 μm) | (3.9 μm) | (1.7 μm) |
| | Void diameter | Acceptable | Acceptable | Acceptable | Acceptable | Acceptable |
| | | (none) | (none) | (none) | (none) | (none) |

TABLE 1C

| | | Comparative | Comparative | Comparative | Comparative | Comparative |
|---|---|---|---|---|---|---|
| | | Example 1 | Example 2 | Example 3 | Example 4 | Example 5 |
| Substrate | | Substrate (1) | Substrate (2) | Substrate (1) | Substrate (1) | Substrate (1) |
| Composition | Metal salt (1) | Tin methane- | Tin methane- | Tin methane- | Tin methane- | Tin methane- |
| of plating bath | | sulfonate | sulfonate | sulfonate | sulfonate | sulfonate |
| | | 170 g/L | 170 g/L | 170 g/L | 170 g/L | 170 g/L |
| | Metal salt (2) | — | — | — | — | — |
| | Acid | Methane- | Methane- | Methane- | Methane- | Methane- |
| | | sulfonic acid | sulfonic acid | sulfonic acid | sulfonic acid | sulfonic acid |
| | | 100 g/L | 100 g/L | 100 g/L | 100 g/L | 100 g/L |
| | Thioamide | — | — | — | — | — |
| | compound | | | | | |
| | Surfactant (1) | Polyoxyethylene- | Polyoxyethylene- | — | — | — |
| | | polyoxypropylene | polyoxypropylene | | | |
| | | adduct of | adduct of | | | |
| | | tristyrenated | tristyrenated | | | |
| | | phenyl ether | phenyl ether | | | |
| | | 1 g/L | 1 g/L | | | |
| | | Tristyrenated | Tristyrenated | — | — | — |
| | | phenyl | phenyl | | | |
| | Surfactant (2) | — | — | Polyoxyalkylene | Polyoxyalkylene | Polyoxyethylene |
| | | | | adduct of | adduct of decyl | adduct of |
| | | | | ethylene | ether | sodium lauryl |
| | | | | diamine | 1 g/L | sulfate |
| | | | | 5 g/L | | 10 g/L |
| | Leveling agent | 2-Chloro- | 2-Chloro- | 2-Chloro- | 2-Chloro- | 2-Chloro- |
| | (1) | benzaldehyde | benzaldehyde | benzaldehyde | benzaldehyde | benzaldehyde |
| | | 0.01 g/L | 0.01 g/L | 0.01 g/L | 0.05 g/L | 1 g/L |
| | Leveling agent | — | — | Methacrylic | Methacrylic | Methacrylic |
| | (2) | | | acid | acid | acid |
| | | | | 0.5 g/L | 40 g/L | 0.5 g/L |
| | Antioxidant | Catechol | Catechol | Catechol | Catechol | Catechol |
| | | 1 g/L | 1 g/L | 1 g/L | 5 g/L | 1 g/L |
| Evaluation | Recess depth | Acceptable | Unacceptable | Unacceptable | Unacceptable | Unacceptable |
| | | (3.7 μm) | (12.6 μm) | (15.1 μm) | (15.3 μm) | (13.0 μm) |
| | Void diameter | Unacceptable | Unacceptable | Unacceptable | Unacceptable | Unacceptable |
| | | (20 μm) | (15 μm) | (25 μm) | (12 μm) | (20 μm) |

TABLE 1D

| | | Reference | Reference | Reference | Comparative |
|---|---|---|---|---|---|
| | | Example 1 | Example 2 | Example 3 | Example 6 |
| Substrate | | Substrate (1) | Substrate (1) | Substrate (1) | Substrate (1) |
| Composition | Metal salt (1) | Tin methane- | Tin methane- | Tin methane- | Tin methane- |
| of plating bath | | sulfonate | sulfonate | sulfonate | sulfonate |
| | | 170 g/L | 170 g/L | 170 g/L | 170 g/L |
| | Metal salt (2) | — | — | — | — |
| | Acid | Methane- | Methane- | Methane- | Methane- |
| | | sulfonic acid | sulfonic acid | sulfonic acid | sulfonic acid |
| | | 100 g/L | 100 g/L | 100 g/L | 100 g/L |
| | Thioamide | — | — | — | — |
| | compound | | | | |
| | Surfactant (1) | Polyoxyethylene- | Polyoxyethylene- | Polyoxyethylene- | 2-Undecyl-1- |
| | | polyoxypropylene | polyoxypropylene | polyoxypropylene | carboxymethyl-1- |
| | | adduct of | adduct of | adduct of | hydroxyelhyl- |
| | | tristyrenated | tristyrenated | tristyrenated | imidazolium- |
| | | phenyl ether | phenyl ether | phenyl ether | betaine |
| | | 100 g/L | 1 g/L | 1 g/L | 1 g/L |
| | | Tristyrenated | Tristyrenated | Tristyrenated | — |
| | | phenyl | phenyl | phenyl | |
| | Surfactant (2) | — | — | — | — |
| | Leveling | 2-Chloro- | 2-Chloro- | 2-Chloro- | 2-Chloro- |
| | agent (1) | benzaldehyde | benzaldehyde | benzaldehyde | benzaldehyde |
| | | 0.01 g/L | 10 g/L | 0.01 g/L | 0.01 g/L |
| | Leveling | Methacrylic acid | Methacrylic acid | Methacrylic acid | Methacrylic acid |
| | agent (2) | 0.5 g/L | 0.5 g/L | 150 g/L | 0.5 g/L |
| | Antioxidant | Catechol | Catechol | Catechol | — |
| | | 1 g/L | 1 g/L | 1 g/L | |
| Evaluation | Recess depth | Unacceptable | Acceptable | Unacceptable | Unacceptable |
| | | (11.2 μm) | (4.1 μm) | (14.6 μm) | (16.0 μm) |
| | Void diameter | Acceptable | Unacceptable | Acceptable | Unacceptable |
| | | (none) | (25 μm) | (none) | (18 μm) |

In Table 1, Examples 1 to 10 are inventive ones fulfilling the requirements of the present invention, all of which Examples had excellent recess filling ability and caused no generation of voids. In these Examples, a tin-copper alloy was used as the tin alloy, but it was confirmed that the above effect of the present invention can be attained even when any other tin alloy (e.g., a tin-silver alloy) is used.

In contrast to this, Comparative Examples 1 to 6 are those which do not fulfil any of the requirements of the present invention.

First, Comparative Example 1 caused generation of voids because of containing no leveling agent in the (B) specified herein.

Comparative Example 2 is one having the same composition, but using a different substrate, as that of Comparative Example 1. Comparative Example 2 had deteriorated recess filling ability and caused generation of voids because of containing no leveling agent in the (B) specified herein. From these results, it is understood that plating baths, when containing no leveling agent in the (B) specified herein, cannot be applied to various kinds of substrates.

Comparative Examples 3 and 4 are ones containing each non-ionic surfactant other than the specific non-ionic surfactant specified herein, and had deteriorated recess filling ability and caused generation of voids.

Comparative Example 5 is one containing no non-ionic surfactant specified herein, but containing another anionic surfactant, and had deteriorated recess filling ability and caused generation of voids.

Comparative Example 6 is one simulating Example 8 of Patent Document 2, and had deteriorated recess filling ability and caused generation of voids because of containing another non-ionic surfactant not specified herein.

Reference Examples 1 to 3 described below are ones, each containing a specific non-ionic surfactant and specific two kinds of leveling agents specified herein, but their concentrations being outside the preferred ones. Even in the case where the composition specified herein is fulfilled, it goes without saying that one having concentrations extremely departed from those specified herein cannot have desired characteristics.

For reference purposes, these Examples are described below.

Reference Example 1 is one excessively containing a specific non-ionic surfactant specified herein, and had deteriorated recess filing ability.

Reference Example 2 is one excessively containing a leveling agent in the (A) specified herein, and caused generation of voids.

Reference Example 3 is one excessively containing a leveling agent in the (B) specified herein, and had deteriorated recess filing ability.

1. A tin or tin alloy electroplating bath comprising:
an inorganic acid and an organic acid, as well as a water-soluble salt thereof;
a non-ionic surfactant selected from the group consisting of polyoxyalkylene phenyl ethers, polyoxyalkylene polycyclic phenyl ethers, and salts thereof,
wherein the phenyl or polycyclic phenyl group in the non-ionic surfactant may be substituted with C₁₋₂₄ alkyl or hydroxy group; and
leveling agents comprising: at least one selected from the group consisting of aliphatic aldehydes, aromatic aldehydes, aliphatic ketones, and aromatic ketones; and at least one selected from the group consisting of α,β-unsaturated carboxylic acids, α,β-unsaturated carboxylic acid amides, and salts thereof.

2. The electroplating bath according to claim 1, wherein the polycyclic phenyl in the non-ionic surfactant is styrenated phenyl, naphthyl, cumylphenyl, nonylphenyl, or styrenated cresol.

3. The electroplating bath according to claim 1, wherein the oxyalkylene in the non-ionic surfactant is at least one selected from the group consisting of ethylene oxide and propylene oxide.

4. The electroplating bath according to claim 3, wherein the oxyalkylene in the non-ionic surfactant is a copolymer of ethylene oxide and propylene oxide.

5. The electroplating bath according to claim 1, further comprising at least one selected from the group consisting of thioamide compounds and non-aromatic thiol compounds.

6. The electroplating bath according to claim 5, wherein the thioamide compounds are thiourea, dimethylthiourea, diethylthiourea, trimethylthiourea, N,N′-diisopropylthiourea, acetylthiourea, allylthiourea, ethylenethiourea, thiourea dioxide, thiosemicarbazide, and tetramethylthiourea; and
the non-aromatic thiol compounds are mercaptoacetic acid, mercaptosuccinic acid, mercaptolactic acid, and water-soluble salts thereof.

7. A process for producing a bump, comprising:
forming a coating film of a tin or tin alloy on a substrate with an electroplating bath as set forth in claim 1; and
then performing reflow treatment.

8. A process for producing a bump, comprising:
forming a coating film of a tin or tin alloy on a substrate with an electroplating bath as set forth in claim 5; and
then performing reflow treatment.
